(19) United States
(12) Patent Application Publication
(10) Pub. No.: US 2024/0311621 A1
(43) Pub. Date: Sep. 19, 2024

(54) DYNAMIC FEATURE SIZE ADAPTATION IN SPLITABLE DEEP NEURAL NETWORKS

(71) Applicant: InterDigital CE Patent Holdings, SAS, Paris (FR)

(72) Inventors: Suresh Kirthi KUMARASWAMY, Rennes (FR); Quang Khanh Ngoc DUONG, Rennes (FR); Alexey OZEROV, RENNES (FR); Patrick FONTAINE, Cesson-Sevigne (FR); Francois SCHNITZLER, Cesson-Sevigne (FR); Anne LAMBERT, Cesson-Sevigne (FR); Ghyslain PELLETIER, Montréal (CA)

(21) Appl. No.: 18/272,714

(22) PCT Filed: Feb. 3, 2022
(86) PCT No.: PCT/EP2022/052633

§ 371 Date: Jul. 17, 2023

(30) Foreign Application Priority Data
Feb. 5, 2021 (EP) 21305156.8

(51) Int. Cl. G06N 3/0464; G06N 3/096

(52) U.S. Cl. CPC G06N 3/0464; G06N 3/096

(57) ABSTRACT

The proposed approach deals with efficient transmission for distributed AI with a provision to switch among multiple bandwidths. During the distributed inference at edge devices, each device needs to load part of the AI model only once, but the input/output features communicated between them can be flexibly configured depending on the available transmission bandwidth by enabling/disabling connection between nodes in the Dynamic feature size Switch (DySw). When some nodes are connected or disconnected in order to achieve the desired compression factor, other parameters of the DNN remain the same. That is, the same DNN model is used for different compression factors, and no new DNN model needs to be downloaded to adapt to the compression factor or the network bandwidth.

### TECHNICAL FIELD

The present embodiments generally relate to dynamic feature size adaptation in splitable Deep Neural Network (DNN).

### BACKGROUND

Artificial intelligence is an important functional block of many technical fields today. This is due to the resurgence of Neural Networks in the form of Deep Neural Networks (DNN). Modern day DNNs are often computationally intensive, thus, it is challenging to execute the DNN operations on mobile phones or other edge devices with low processing power. This is often addressed by transferring the data from the mobile devices to the cloud server, where all the computations are done.

### SUMMARY

According to an embodiment, a device is presented, comprising: a Wireless Transmit/Receive Unit (WTRU), comprising: a receiver configured to receive a part of a Deep Neural Network (DNN) model, wherein said part is before a split point of said DNN model, and wherein said part of said DNN model includes a neural network to compress feature at said split point of said DNN model; one or more processors configured to: obtain a compression factor for said neural network, determine which nodes in said neural network are to be connected responsive to said compression factor, configure said neural network responsive to said determining, and perform inference with said part of said DNN model to generate compressed feature; and a transmitter configured to transmit said compressed feature to another WTRU.

According to another embodiment, a device is presented, comprising: a Wireless Transmit/Receive Unit (WTRU), comprising: a receiver configured to receive a part of a Deep Neural Network (DNN) model, wherein said part is after a split point of said DNN model, and wherein said part of said DNN model includes a neural network to expand feature at said split point of said DNN model, wherein said receiver is also configured to receive one or more features output from another WTRU; and one or more processors configured to: obtain a compression factor for said neural network, determine which nodes in said neural network are to be connected responsive to said compression factor, configure said neural network responsive to said determining, and perform inference with said part of said DNN model, using said one or more features output from another WTRU as input to said neural network.

According to another embodiment, a method is presented, comprising: a method performed by a Wireless Transmit/Receive Unit (WTRU), the method comprising: receiving a part of a Deep Neural Network (DNN) model, wherein said part is before a split point of said DNN model, and wherein said part of said DNN model includes a neural network to compress feature at said split point of said DNN model; obtaining a compression factor for said neural network; determining which nodes in said neural network are to be connected responsive to said compression factor; configuring said neural network responsive to said determining; performing inference with said part of said DNN model to generate compressed feature; and transmitting said compressed feature to another WTRU.

According to another embodiment, a method is presented, comprising: receiving a part of a Deep Neural Network (DNN) model, wherein said part is after a split point of said DNN model, and wherein said part of said DNN model includes a neural network to expand feature at said split point of said DNN model; receiving one or more features output from another WTRU; obtaining a compression factor for said neural network; determining which nodes in said neural network are to be connected responsive to said compression factor; configuring said neural network responsive to said determining; and performing inference with said part of said DNN model, using said one or more features output from another WTRU as input to said neural network.

Further embodiments include systems configured to perform the methods described herein. Such systems may include a processor and a non-transitory computer storage medium storing instructions that are operative, when executed on the processor, to perform the methods described herein.

### BRIEF DESCRIPTION OF THE DRAWINGS

FIG. 1A is a system diagram illustrating an example communications system in which one or more disclosed embodiments may be implemented, and FIG. 1B is a system diagram illustrating an example wireless transmit/receive unit (WTRU) that may be used within the communications system illustrated in FIG. TA according to an embodiment.

FIG. 2 illustrates a mechanism for a distributed AI between two devices without feature size compression.

FIGS. 3A, 3B and 3C illustrate a DNN with one, two, and three candidate splits for feature compression, respectively.

FIG. 4 illustrates a DNN with a single split for feature compression.

FIG. 5A illustrates a feature size compression mechanism for a distributed AI between two devices, Device-1 and Device-2, using a bandwidth-reducer (BWR) and bandwidth-expander (BWE), where a single compression factor is supported, and FIG. 5B illustrates a feature size compression mechanism where multiple compression factors are supported.

FIG. 6A illustrates the total inference latency without the BWR and BWE, and FIG. 6B illustrates the total inference latency with the BWR and BWR, where the size of the intermediate data may be reduced.

FIG. 7 illustrates a process to dynamically switch between splits and compression factor (CF) configurations, according to an embodiment.

FIG. 8A shows Devices 1 and 2 estimating their compute capability and the transmission channel, FIG. 8B illustrates the reception of the AI/ML model from each of the devices, and FIG. 8C illustrates the inference time operations of the devices.

FIG. 9 illustrates a method with a single split in a DNN for adaptive feature compression, according to an embodiment.

FIG. 10 illustrates an example DySw capable of reducing and expanding an input of size 4.

FIG. 11 illustrates the connections of DySw configurations shown in FIG. 9.

### DETAILED DESCRIPTION

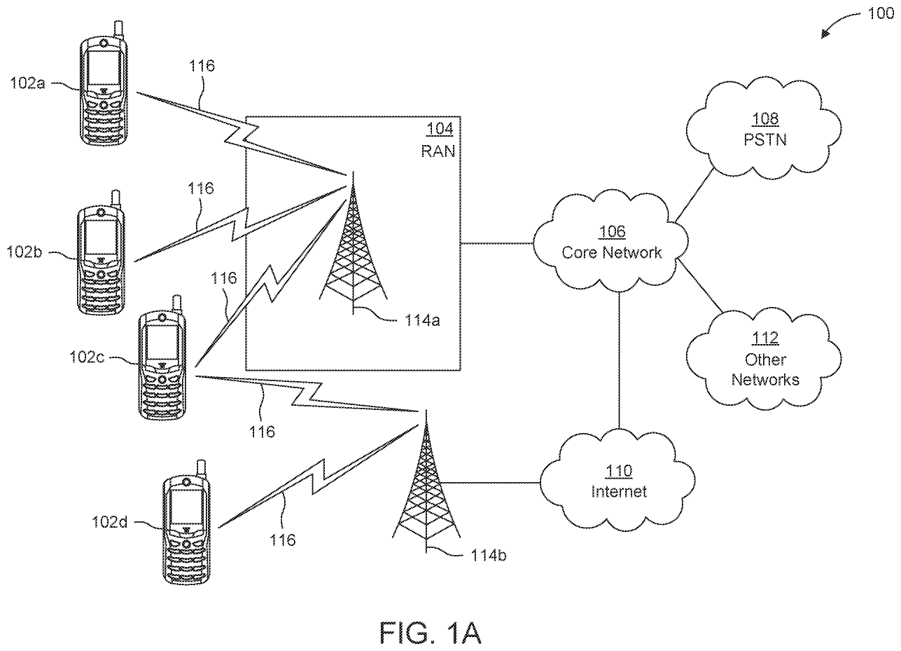

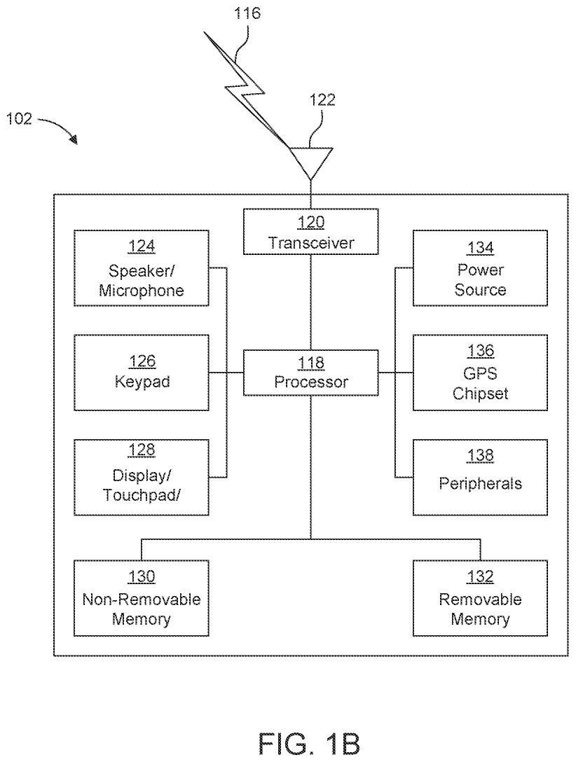

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104, a CN 106, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., a eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106.

The RAN 104 may be in communication with the CN 106, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104 and/or the CN 106 may be in direct or indirect communication with other RANs that employ the same RAT as the RAN 104 or a different RAT. For example, in addition to being connected to the RAN 104, which may be utilizing a NR radio technology, the CN 106 may also be in communication with another RAN (not shown) employing a GSM, UMTS, CDMA 2000, WiMAX, E-UTRA, or WiFi radio technology.

The CN 106 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, abase station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

Although the WTRU is described in FIGS. 1A-1B as a wireless terminal, it is contemplated that in certain representative embodiments that such a terminal may use (e.g., temporarily or permanently) wired communication interfaces with the communication network.

In view of FIGS. 1A-1B, and the corresponding description of FIGS. 1A-1B, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

As described above, the execution of DNN operations is often addressed by transferring the data from the mobile devices to the cloud server, where all the computations are done. However, this is bandwidth demanding, time intensive (due to transmission latency), and raises data privacy concerns. One way this can be solved is by doing all computation on the user devices (e.g., mobile phones) through lightweight and less accurate DNNs. The other way is through DNN with high accuracy but by sharing the computation across single/multiple mobile devices and/or the cloud.

### Flexible AI Methods

To run DNN models on the user devices only, model compression techniques are widely exploited. They allow reducing model memory footprint and runtime to fit it to a particular device. However, one might not know upfront on which device the model will be executed and yet, even if the device is known, its available resources might vary over time due to, e.g., other processes. To overcome these issues, a family of so-called Flexible AI models was proposed recently. Those models can instantly adapt to the available resources through, e.g., allowing early classification exits, adapting model width (slimming), or allowing switchable model weights quantization.

### Distributed AI Methods

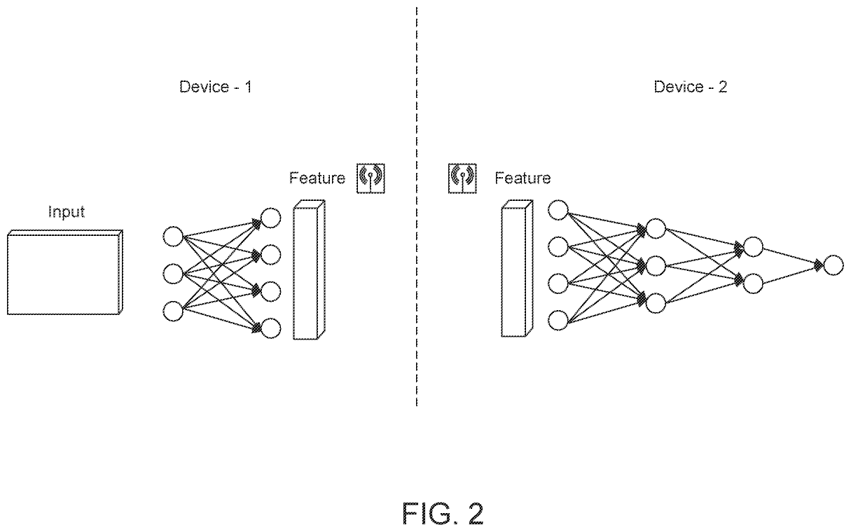

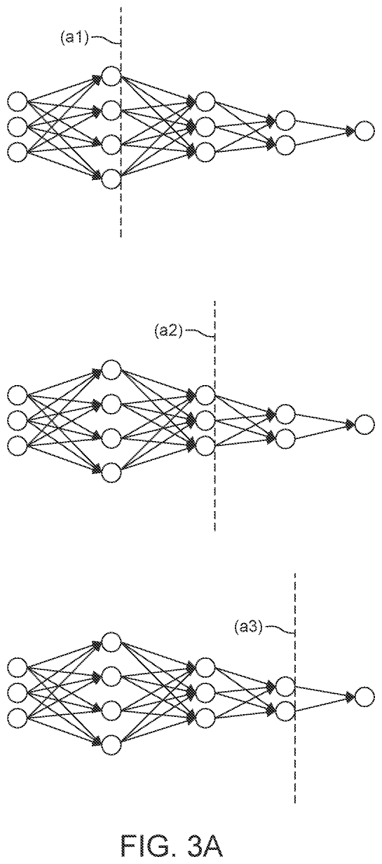

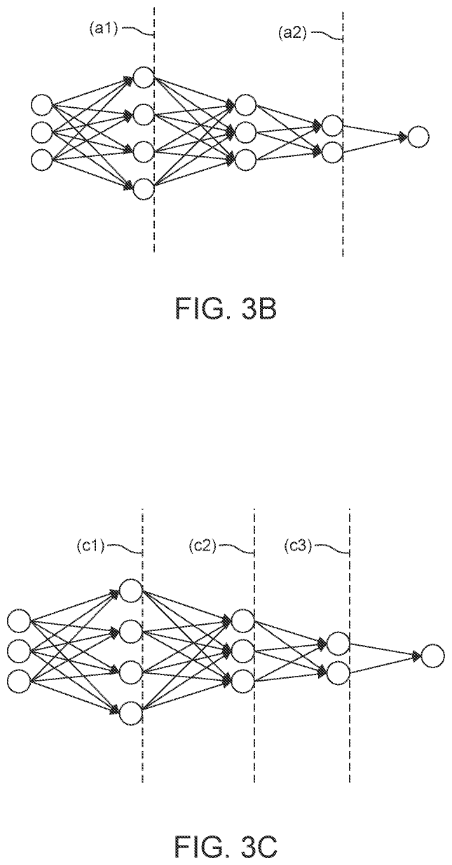

Some of so-called distributed AI methods split a model between two or more devices (i.e., WTRUs) or between a device and cloud/edge. For example, FIG. 2 illustrates a mechanism for a distributed AI between 2 devices, Device-1 and Device-2, without feature size compression. In distributed AI, intermediate data (feature) that might be of quite high dimension needs to be transmitted. This adds a latency in the processing and is not always possible due to bandwidth limits of the corresponding transmission network. To overcome this issue, methods reducing the feature size via a bottleneck were proposed. FIG. 3A illustrates a DNN with one candidate split for feature compression, where a1, a2, or a3 can be used as the split points. FIG. 3B illustrates a DNN with two candidate splits (e.g., a1 and a2) for feature compression. FIG. 3C illustrates a DNN with three candidate splits (e.g., c1, c2 and c3) for feature compression.

Without introducing any limitation, a feature may be considered as an individual measurable property or characteristic of data that may be used to represent a phenomenon. One or more features may be related to the inputs and/or outputs of a machine learning algorithm, of a neural network and/or of one of its layers. For example, features may be organized as vectors. For example, features associated with wireless use cases may include time, transmitter identity, and measurements on Reference Signals (RS).

For example, features associated to an algorithm used to process Positioning information may include values associated with a measurement of a positioning RS (PRS), of a quantity such as Reference Signal Receive Power (RSRP), of a quantity such as Reference Signal Receive Quality (RSRQ), of a quantity related to a Received Signal Strength Indication (RSSI), a quantity related to a time difference measurement based on signals of separate sources (e.g., for time-based positioning methods), of a quantity related to an angle of arrival measurement, of a quantity related to the quality of a beam, and/or output from a sensor (WTRU rotation, imaging from a camera, or the likes).

For example, features associated to an algorithm used to process Channel State Information (CSI) may include measurements of a quantity associated with reception of Channel State Reference Signal (CSI-RS), of a Synchronization Signal Block (SSB), Precoding Matrix Indication (PMI), Rank Indicator (RI), Channel Quality Indicator (CQI), RSRP, RSRQ, RSSI or the likes.

For example, features associated to an algorithm used to process beam management and selection may include a quantity associated with similar measurements as for processing CSI, a Transmit/Receive Point (TRP) identity (ID), a beam ID and/or one or more parameters related to Beam Failure Detection (BFD) e.g., thresholds determination of sufficient beam quality.

Similarly, any method described herein may further be applied to, or include specific parameter settings for, hyperparameters used for the machine learning algorithm for a specific phase of the AI/ML processing e.g., training or inference.

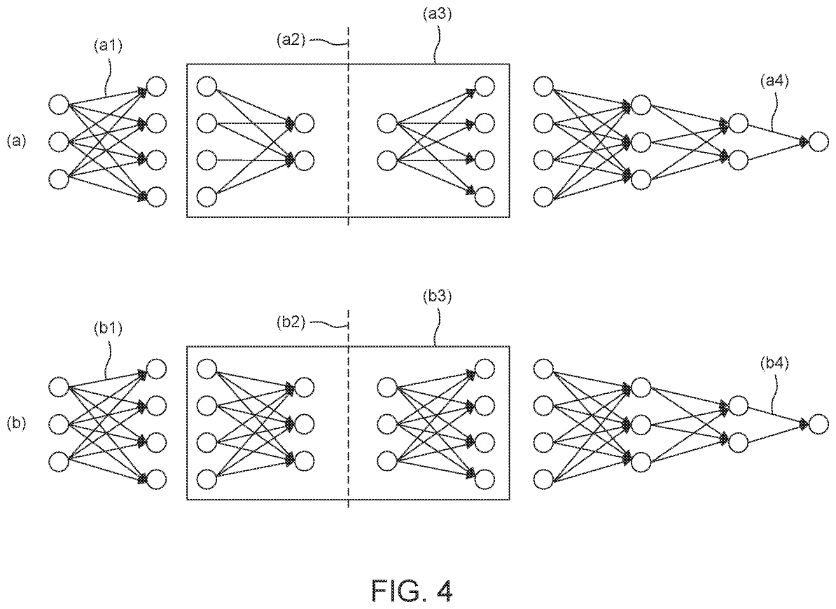

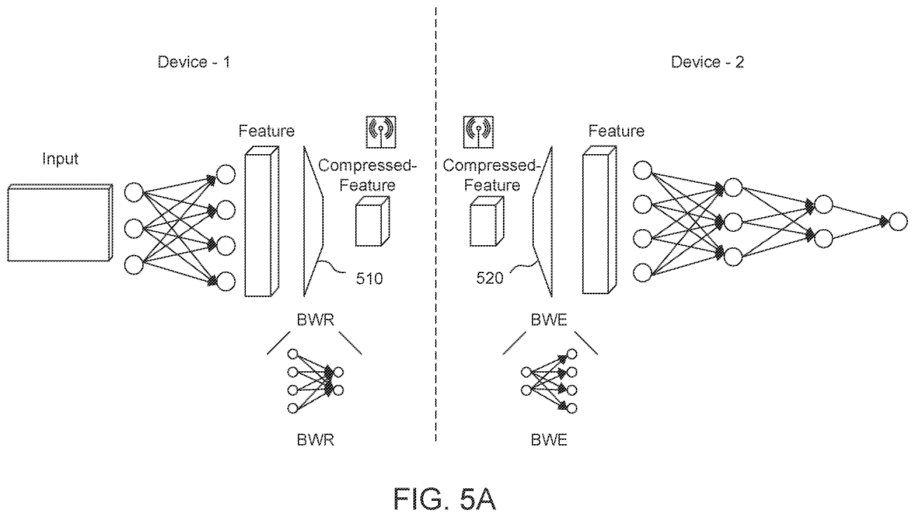

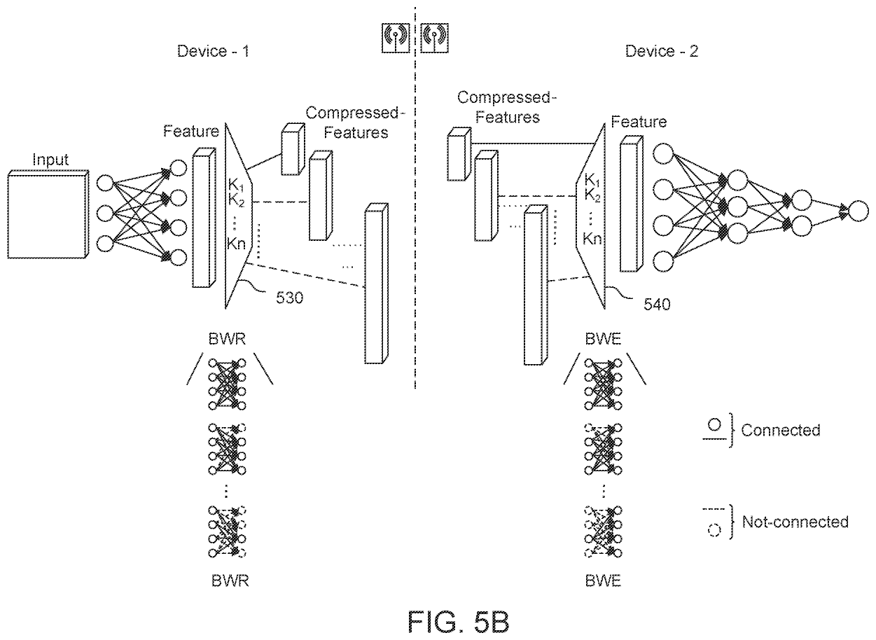

FIG. 4 illustrates a DNN with a single split (a2, b2 respectively) for feature compression, where the feature size is reduced from (a) 4 to 2 and (b) 4 to 3. In particular, (a3) is a subnetwork realizing 4 to 2 feature size reduction and (b3) reducing from 4 to 3. In existing works, a DNN is trained from scratch with a feature compressor and expander for each compression factor. Note that compression factor is the ratio of feature size at the output of the compressor and the feature size at the input to the compressor. This means whenever there is a need to change the compression factor the devices and the cloud-server has to co-ordinate and freshly download a new model from the cloud server. FIG. 5A illustrates a feature size compression mechanism for a distributed AI between two devices, Device-1, and Device-2, using a bandwidth-reducer (BWR, 510) and bandwidth-expander (BWE, 520), where a single compression factor is supported. However, those methods do not allow adapting the bottleneck to different transmission network bandwidths.

To provide flexibility in distributed AI paradigms, we introduce a Flexible and Distributed AI (FD-AI) approach. The proposed approach is distributed since the DNN can be split among two or more devices. The proposed approach is also flexible because the split points can be chosen among several possible split point candidates, depending upon the available resource in the devices. In addition, the transmitted feature size at each split point can be compressed to suit the available network bandwidth for the transmission.

In one embodiment, we propose switchable bottleneck subnetworks which are parts of the DNN architecture. The bottleneck subnetworks are switchable as they may adapt to different transmission network bandwidths at the time of inference. In the proposed design we have one bottleneck subnetwork having layers to reduce the feature size and other set of layers to revert it back to the original size. These bottleneck subnetworks can be incorporated at one or more split positions of any existing DNNs. For brevity, in the following descriptions, we consider a DNN with a single split with one set of bottleneck subnetworks for feature size reduction and expansion.

In one example, the first device may be either an edge device or a cloud server, and the second device may be either an edge device or a cloud server. More generally, the methods described herein may be applied to any device exchanging data over a communication link. Such device may include processing of a split neural network, or an autoencoder function. Methods described herein may be applicable to processing in a device e.g., for an end-user application (e.g., audio, video, or the likes) or for a function related to a processing for transmission and/or reception of data. More generally, such device may be a mobile terminal, a radio access network node such as gNB or the likes. Such communication link may be a wireless link and/or interface such as 3GPP Uu, 3GPP sidelink or a Wifi link.

The DNN layers up to the split point with the feature size reducing layers of bottleneck subnetwork are loaded on to the first device. The remaining part, i.e., the bottleneck subnetwork expander and the rest of the DNN after the split point are loaded on to the second device. We refer to the bottleneck subnetwork comprising of reducers and expander as Dynamic feature size Switch (DySw). The feature to be transmitted to the second device is extracted at the middle of the DySw. We call the DNN realizing this a Dynamic Switchable Feature Size Network (DyFsNet). DyFsNet generally applies to any DNN architecture such as convolutional neural network (CNN), and it is novel in design and training. The inferencing in DyFsNet is simple and adjustable (with respect to the split-positions and available network bandwidths).

FIG. 5B illustrates an example of a feature size compression mechanism that supports multiple compression factors for a distributed AI between two devices, Device-1, and Device-2, using a bandwidth reducer (BWR) and bandwidth expander (BWE), where K₁, K₂, . . . , KN specify the compression factors inside the trainable BWR (530) and BWE (540), which are exclusive and dynamically switchable at the time of inference.

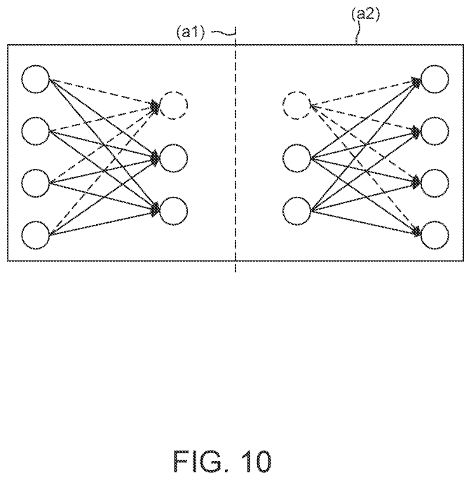

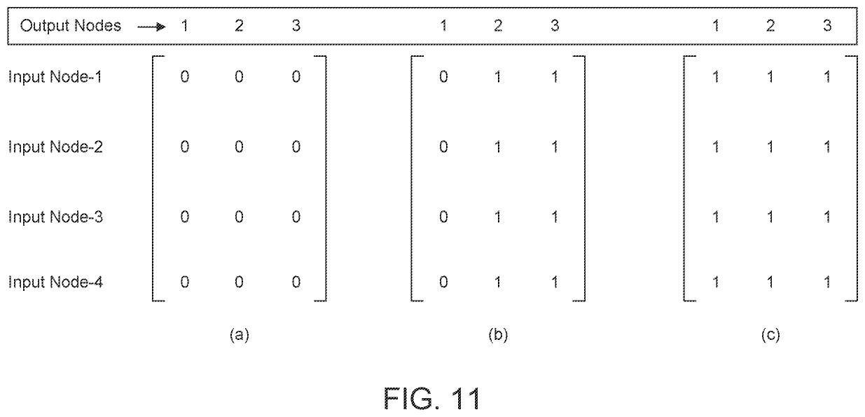

More specifically, Device-1 and Device-2, optionally with a server, monitor the channel conditions and device status, and select the compression factor and the feature size at the split location. Device-1 receives the first part of a DNN model up to the split location and Device-2 receives the remaining part of the DNN model. At Device-1, inference is performed to calculate the feature from the input and then compressed by the BWR. As described in more details in association with FIG. 10 and FIG. 11, by controlling which nodes are connected in the BWR (530), different compression factors can be obtained. At Device-2, the compressed feature is received and expanded by the BWE (540). Similar to the BWR, BWE can control the compression factor by controlling the node connection in the BWE. Then Device-2 continues the inference and provides the final output.

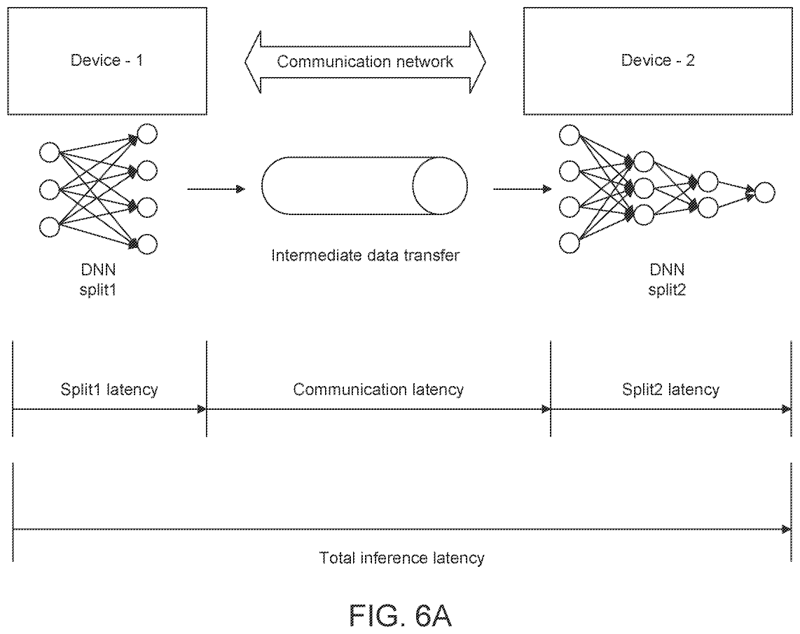

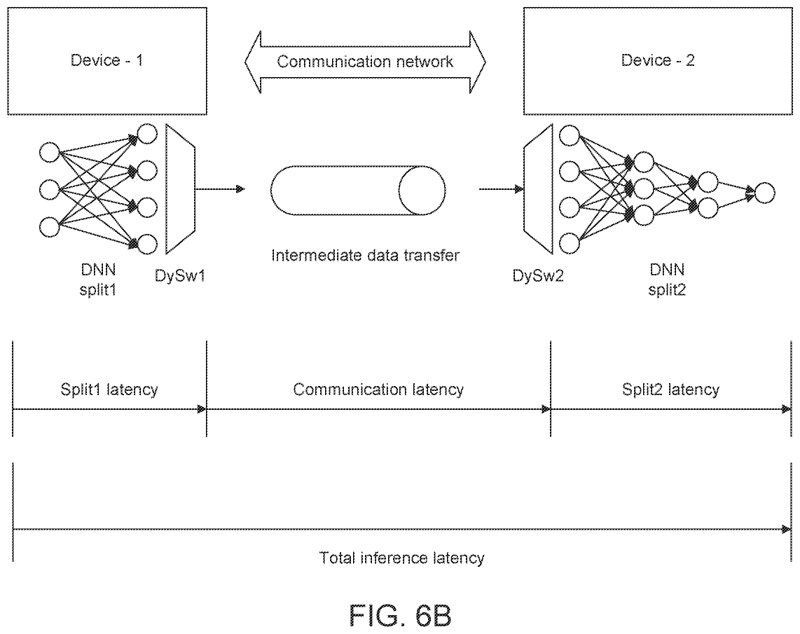

Network bandwidth restrictions introduce additional latency on the overall inferencing. FIG. 6A illustrates the total inference latency without the BWR and BWE. FIG. 6B illustrates the total inference latency with the BWR and BWR, where the size of the intermediate data may be reduced.

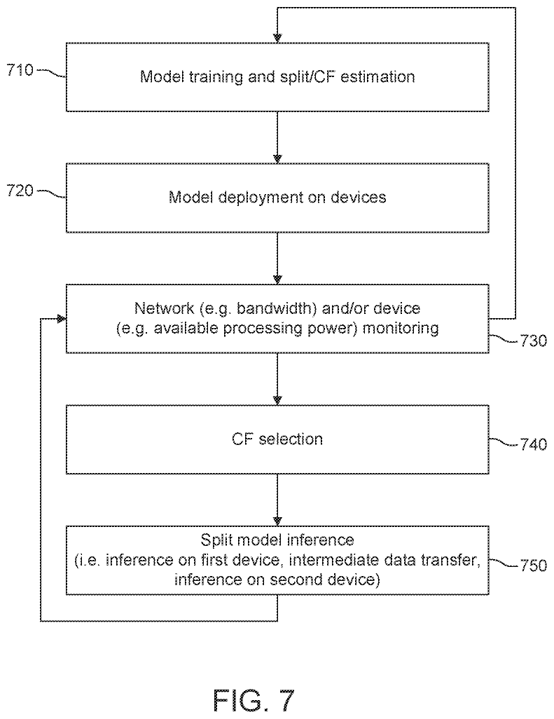

As described above, we propose a method to reduce intermediate data sizes at different positions in the DNN model to limit throughput requirement on the communication network while nearly maintaining the accuracy of the predictions. FIG. 7 illustrates a process to dynamic switch between split/compression factor (CF) configurations, according to an embodiment.

During the model training and split/CF estimation stage (710), the DyFsNet model is trained for different splits and CFs. This can be currently done offline in the cloud server. The trained model is saved in the cloud server and is available for downloading for the devices. The orchestrator (in the server side) manages the co-ordination of trained model selection and transmission to the end devices based on the request. Here it is assumed that the information about the bandwidth is available. Based on this, the CF is estimated as the ratio of the feature size and the available bandwidth.

For example, an orchestrator or external control system determines the split location for the DNN based on the compute ability of the end devices (e.g., in Device-1 and Device-2). This is communicated to the devices which load the DNN for procession in accordance to the split information.

At the model deployment stage (720), trained split models are received by the devices. Once received they are loaded on the device for inferencing.

The network (e.g., bandwidth) and/or device (e.g., available processing power) status are monitored (730). The devices monitor the network channel between them and co-ordinate CFs among themselves. This is done without involving the server.

Once the consensus is reached among the devices, the CF selection (740) is done thus impacting the feature size at the split locations. Note, available CF options depend on the number of channels in the filters of the DNN layer at which the split is realized. Normally CF is chosen to nearly match and not exactly the bandwidth available.

The split model inference is performed on the first device and second device (750). For example, the first device computes intermediate feature using the DNN up to the split, compresses the feature, transfers the compressed feature to the second device. The second device receives the compressed feature uncompressed it and continues with the DNN inference. In one embodiment where a device is a wireless terminal device and/or the communication link of the device is a wireless air interface (e.g., such as a NR Uu, sidelink or the likes), the device may perform at least one of the following:
Initiate an adaptation proposed herein. For example, the device may adapt the split processing points, the feature dimensions, the compression factor, inference latency, processing requirements, accuracy of function, or any other aspect proposed herein.
The device may trigger such adaptation for AI processing upon determination of at least one of the following in relation to L1/physical (PHY) layer operation:
   The device may determine that a change in radio characteristics has occurred, where such characteristics may impact the transmission data rates over the interface, such as a change in the identity of a cell, a change in carrier frequency, a change of bandwidth part (BWP), a change in the number of physical resource blocks (PRB) of the BWP and/or of the cell, a change in sub-carrier spacing (SCS), a change in the number of aggregated carriers available for transmissions, a change in available transmission power, a change in measured quantities or the likes.
   The device may determine that a change in the operating conditions over the wireless interface as occurred, such as a change of the control channel resources (CORESET) or identity, where a first identity may be associated to a first threshold and a second identity may be associated to a second threshold.
   The device may determine that the change is above a specific, possible configured, threshold indicating deterioration of the channel quality and may perform an adaptation that would lower the data rate associated with the AI processing. Conversely, the device may determine an improvement in radio conditions and perform an adaptation that may increase the data rate associated with the AI processing.
For example, this may be applicable to a physical layer function of the device such as CSI autoencoding.
The device may trigger such adaptation for AI processing upon determination of at least one of the following in relation to L2/Medium Access Control (MAC) layer operation:
   The device may determine that a change in data processing, information bearer (e.g., data radio bearer, signalling radio bearer) has occurred, where such characteristics may impact the transmission data rates over the interface available to the AI processing, such as a change in Logical Channel Prioritization parameters e.g., Packet Delay Budget (PDB), Prioritized Bit Rate (PBR), TTI duration/numerology, a change in the associated QoS flow ID, mapping restriction towards a set of resources enabling a different data rate, or the likes.
   The device may determine that the change is above a specific, possible configured, threshold indicating a decrease in the available data rate for the AI processing and may perform an adaptation that would lower the data rate associated with the AI processing. Conversely, the device may determine an increase in available data rate and perform an adaptation that may increase the data rate associated with the AI processing.
For example, this may be applicable to a system level function such as a positioning function of the device. For example, this may be application to a specific data radio bearer (DRB) and/or DRB type e.g., a DRB associated with a specific AI-enabled application such that a change in a DRB or its characteristics may trigger an adaptation of an AI-based processing at the associated application layer.
The device may trigger such adaptation for AI processing upon determination of at least one of the following in relation to L3/Radio Resource Control (RRC) layer operations:
   The device may determine that a change in configuration has occurred e.g., impacting one or more of the L1/L2 configuration such as aspects described above that may change the available data rates.
   The device may determine that it has received and/or that it shall apply (e.g., for a conditional handover command) a reconfiguration message e.g., for mobility has been received, where the message may include an indication of applicable data rate for AI processing and/or its related radio bearers.
   The device may determine that a radio link impairment has occurred, such as a radio link failure (RLF).
   The device may determine that the change is above a specific, possible configured, threshold indicating a decrease in the available data rate for the AI processing and may perform an adaptation that would lower the data rate associated with the AI processing. Conversely, the device may determine an increase in available data rate and perform an adaptation that may increase the data rate associated with the AI processing. Alternatively, it may determine that the event itself may be associated with an increase (e.g., addition of a cell to the connectivity of the device's configuration e.g., dual connectivity) or a decrease (e.g., RLF and/or removal of a cell to the connectivity of the device's configuration) of the available data rates for the AI processing.
The device may trigger such adaptation for AI processing upon determination of at least one of the following in relation to available processing resources:
   The device may determine that a change in available hardware processing has occurred, e.g., based on a change in the number of instantiated and/or active AI processes, based on a change in dynamic device capabilities, or based on a change in processing requirement (e.g., inference latency, accuracy) for the AI processing.
   The device may determine that a change in power state of the device has occurred. For example, the device may determine that it has transited from a first state to a second state, where such states may be related to a RRC connectivity state (IDLE, INACTIVE or CONNECTED), a DRX state (active, inactive) or a different configuration thereof.
   The device may determine that the change is above a specific, possible configured, threshold indicating a decrease in the available processing resources. Conversely, the device may determine an increase in available processing resources and perform an adaptation that may increase the data rate associated with the AI processing. Similarly, a specific state may be associated with a specific AI processing level, split point configuration and/or data rate associated.
The device may trigger such adaptation for AI processing upon determination that it receives control signalling according to at least one of the following:
   The device may receive control information that indicates either an increase or a decrease in AI processing/available data rates for AI processing. This may be implicitly based on a signalled value and/or a modification of the control channel property a value such as described above for L1, L2, L3 processing and/or for power saving management, or explicitly using an indication in the control message. Such control information may be received in a L1 signal, a L1 message e.g., a DCI on PDCCH, in a L2 MAC control element or in a RRC message.
   The control information may include the specific split point configuration to apply for a given AI processing, hyperparameters settings, target resolution, target accuracy, target feature vector or the likes.

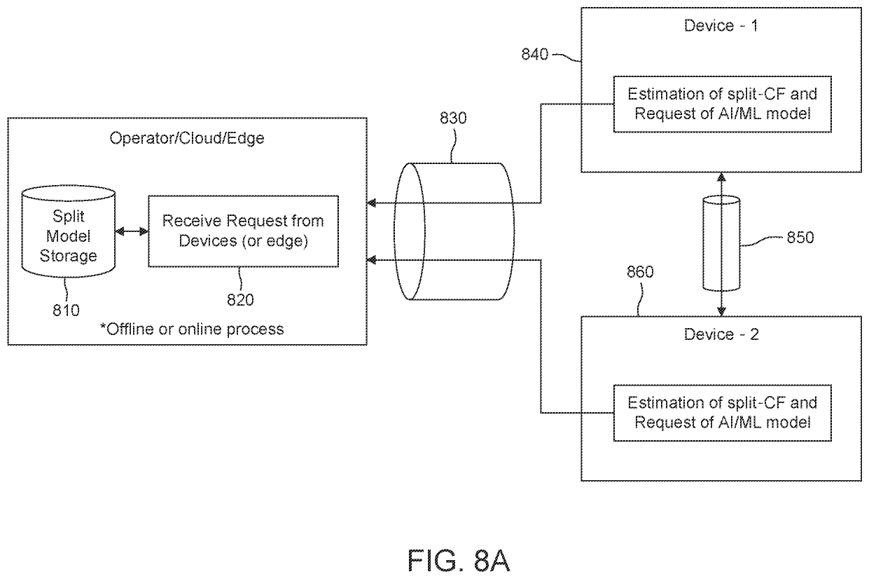

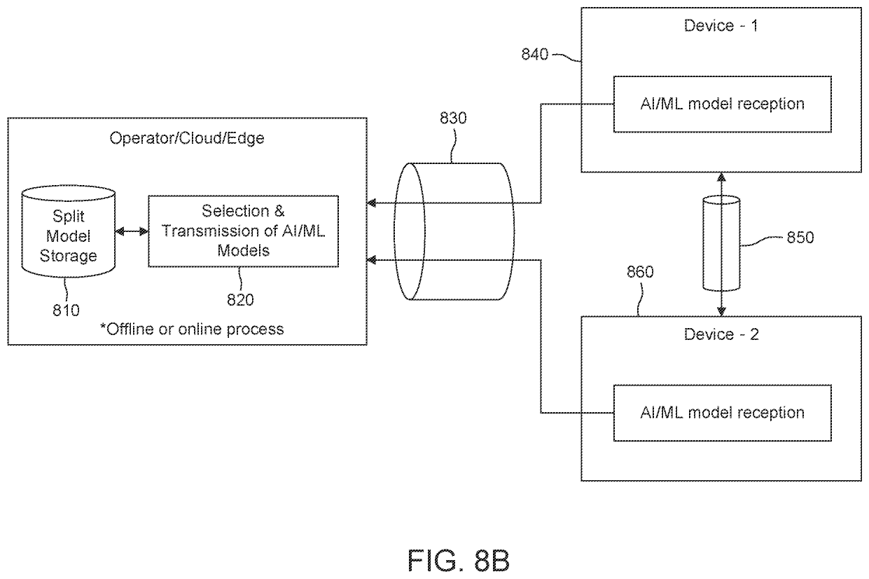

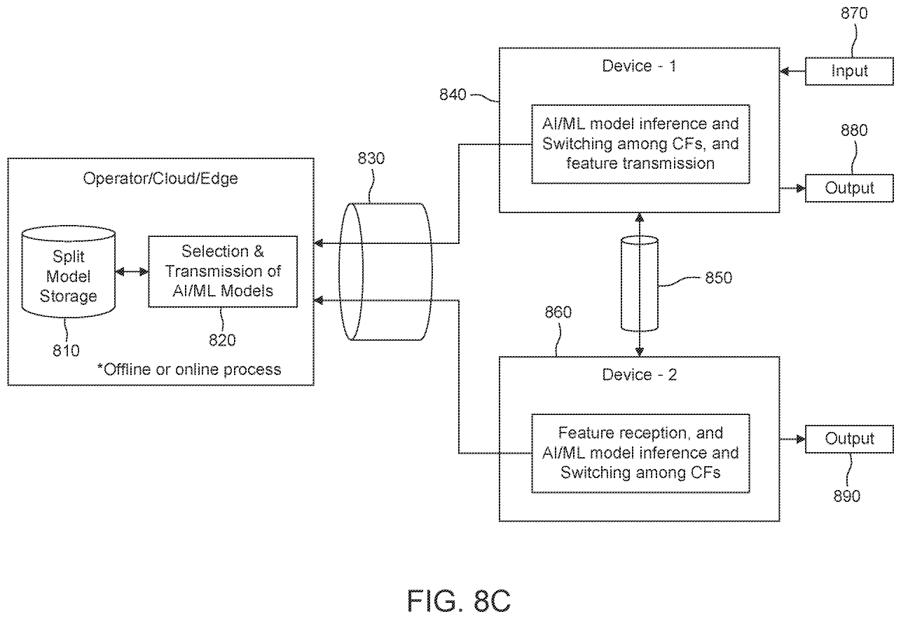

FIGS. 8A, 8B and 8C provide an alternate view of the process. FIG. 8A shows that Devices 1 and 2 (840, 860) estimate their compute capability and the transmission channel (850). Their estimations are conveyed (820, 830) to the operator/edge/cloud and a suitable AI/ML model (810) is requested.

In FIG. 8B, the reception of the AI/ML model from each of the devices is shown. The operator/cloud/edge performs selection of the model and transmits the model by network (830), and the requested model is received by devices 1 and 2.

FIG. 8C depicts the inference time operations of the devices. Device-1 calculates the feature and then based on channel conditions the feature size of appropriate dimension is transmitted to Device-2. Device-1 performs inference on input data (870). The input data could be one or many images from the device memory or that captured live from the camera of the device, or audio data on the device memory or captured live from the device microphone or any other data that needs to be processed by a DNN. Device-1 outputs an intermediate or early output (880) processed by the DNN such as in the case of MSDNet type of DNN. The information required for further processing of the feature is also communicated via channel (850) to Device-2. Device-2 receives the feature, further continues the inference and switching the CF if required, and provides the final output (890). Additionally, Device-1 transmits the feature to the Device-2 along with control information to further process the feature. Device-2 receives the feature and control information, and continues with the inference.

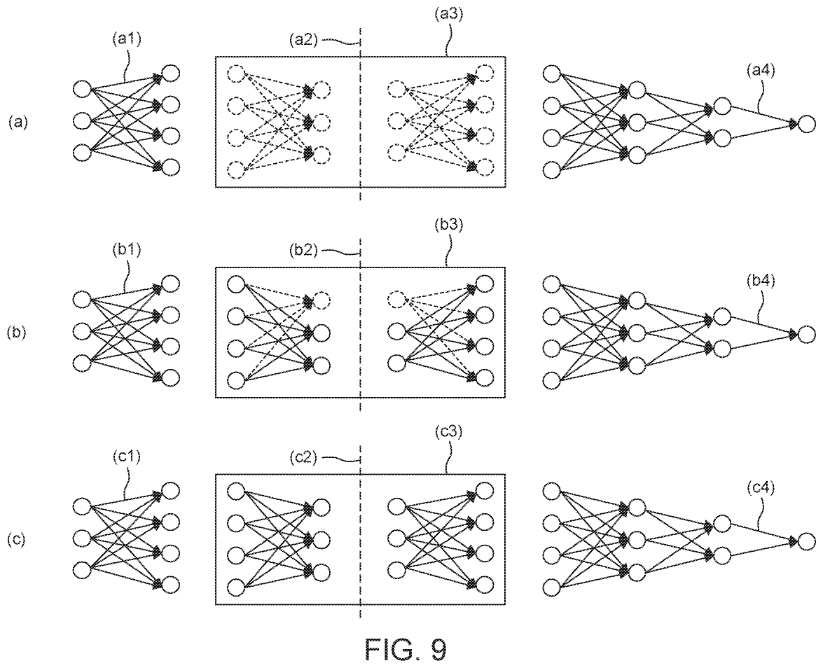

FIG. 9 illustrates a proposed method with a single split in a DNN for feature compression. FIG. 9(a) depicts jointly trained subnetwork DySw (a3) without compression factor selected. FIG. 9(b) depicts jointly trained subnetwork (b3) with feature compression factor 4 to 2 selected. FIG. 9(c) depicts jointly trained subnetwork (c3) with feature compression factor 4 to 3 selected. Note that the DNN in FIGS. 9(a), (b) and (c) is the same (single) DNN.

The DySw can be trained together with the entire DNN. Alternatively, the DNN without the DySw is pretrained, and the DySw subnetwork is added. Note in this alternative solution, the pretrained DNN is augmented with DySw (a3) subnetwork and training is only for the DySw while keeping the pretrained (weights of) DNN unchanged (i.e., fixed).

As illustrated in FIG. 9, the DySw is reconfigurable to suit multiple compression factors. The reconfiguration is realized through connection details of the DySw nodes. For example, for a DySw subnetwork as illustrated in FIG. 10, we can maintain a matrix of size 4×3 specifying the node connections as shown in FIG. 11. Each element (Eᵢⱼ) in the matrix represents whether input node i is connected to output node j, where ‘0’ represents disconnected, and ‘1’ connected. The matrices as shown in FIGS. 11(a), (b) and (c) correspond to FIGS. 9(a), (b) and (c), respectively. In particular, FIG. 9(a) specifies that none of the input nodes is connected to any output nodes, FIG. 9(b) specifies that only 2 of the output nodes (output node-2 and node-3) are connected to the input nodes, and FIG. 9(c) specifies that all the nodes of input are connected to the output. FIG. 11 shows the connection on the reducer side, and the expander can maintain matrices corresponding to different compression factors. In one example, the shape of the matrix at the expander side is transposed (with respect to the one at the reducer side) but the number of all-zero rows will remain the same.

As illustrated in FIG. 8, the devices coordinate the CF. In one embodiment, an orchestrator or external control system informs Device-1 about the available bandwidth. Device-1 determines the CF to be used based on the information about the bandwidth. Device-1 then switches the DySw to realize the feature size compression corresponding to the determined CF. Device-1 may also communicate the CF it is using and accordingly Device-2 switches its side of the DNN to suit the communicated information.

In one embodiment, after the CF is selected, Device-1 decides which connections should be disabled between nodes to provide the selected the CF, and Device-2 also decides which connections should be disabled correspondingly in order to properly perform the expansion. The CF determines how many output nodes are connected to the input nodes, but the way and how many will be determined through learning.

As described above, FIG. 10 illustrates an example DySw capable of reducing and expanding an input of size 4. Note that while FIG. 10 illustrates a single layer “reducer” block for simplicity, the reducer is not limited to a single layer. The illustrated DySw is capable of compression from 4-to-3, 4-to-2 and 4-to-1 and the corresponding expansions (i.e., 1-to-4, 2-to-4 and 3-to-4). DySw design may have additional layers if need, for example, BatchNorm layer for better training. Here we illustrate only the reducer (BWR shown to the left of the dotted line) and expander (BWE shown to the right of the dotted line). The non-linearity is implicit to the layers. BatchNorm layer can be an optional layer required for efficient training, hence not shown here.

More generally, a typical DySw comprises four types of layers, namely feature dimensionality reducer and expander layers, non-linearity layers and batch normalization (BatchNorm) layers. Of these layers the BatchNorm layer is optional. A simple DySw is shown in FIG. 10.

The DySw used in a DNN classifiers can be trained using the conventional task-specific loss, for example, cross-entropy loss for classification tasks or mean-square error loss for regression tasks. The DySw can be used for any task, namely classification, detection, or segmentation, and in any DNN architecture, namely CNN, GAN, Auto-encoder etc. Training a DySw involves learning reducer-expander layer weights and the parameters of batch normalization layer (also denoted as “BatchNorm”). BatchNorm is used for faster convergence of training.

The DySw training allows for additional constraints to the loss objective. As an illustration we show adding of reconstruction-loss across DySw. The reconstruction loss penalizes the disparity between the input to and output to the DySw. The DySw is an auxiliary and optional entity which can be added to a trained DNN.

In DySw the reduction factor is switchable on the fly at the time of inference. In DyFsNet the training iterations are modified to co-learn shared DySw weights with multiple reduction factors, as detailed further below.

The training of DySw can be offline or online, done on the cloud/operator/edge or it may be a federated training on the devices. We describe here the architecture and training of Split DNN for a case of single split between two devices with a DySw. The training mechanism described here may be extended to multiple split cases. In the following, we describe in detail the architecture of the split DNN, architecture of the DySw layer and DyFsNet (a DNN with a DySw layer), and different loss functions and their training.

Consider a split at the end of l-th layer, with Device-1 processing up to layer-l and Device-2 processing from layer l+1 onwards. Let part of the DNN in Device-1 be h_{device1} and similarly let h_{device2} be the part of DNN in Device-2. Though the input to the DNN can be any type of data, for now let input X be a color-image such that X∈R^{{W×H×3}}, where W, H are width, height, and 3 represents the number of color channels (e.g., RGB). The feature tensor (or simply feature) at the split is yₗ∈R^{{M×N×C}}, where M, N and C represent its width, its height, and the number of channels. The feature yₗ is transmitted over the wireless network to Device-2 which takes yₗ as the input and produces output Y. Thus, yₗ=h_{device1}(X), Y=h_{device2}(yₗ).

DySw is a subnetwork represented by h_{DySw}. The parameters of h_{DySw} are θ_{DySw}. Let the reducer (first part) and expander (second part) of the DySw be referred as BWR and BWE, an example implementation of such reducer and expander can include a convolutional layer, a non-liner layer (ReLu), and a batch normalization layer (BatchNorm) as summarized below:

θ_{DySw}=[θ_{DySw}_{_{BWR}};θ_{DySw}_{_{BWE}}]

θ_{DySw}_{_{BWR}}=[layer_{conv}_{_{DySwBWR}};ReLu;BatchNorm]

θ_{DySw}_{_{BWE}}=[layer_{conv}_{_{DySwBWE}};ReLu;BatchNorm]

The DNN with DySw is referred as DyFsNet. Let DyFsNet be represented by h. Let θ be the parameters of h. The subnetwork of DyFsNet before the split point is h_{device1}_{_{BWR}} and the subnetwork after the split point is h_{device2}_{_{BWE}}.

DySw switches among various compression factors (CF) of the feature size. The CF switching is indexed by K. The intermediate outputs, indexed by K, at the split of DyFsNet are as follows,

y′₂_{_{K}}=h_{DySw}_{_{BWR}}(y₂)

[symbol]

=h_{DySw}_{_{BWE}}(y′_{2K})

Ŷ=h_{device2}( [symbol] )

where h_{DySw}_{_{BWR}} and h_{DySw}_{_{BWE}} are the DySw subnetwork doing BWR and BWE respectively,

$${y}_{{2}_{K}}^{′} ∈ {R}^{\{ M \times N \times \frac{C}{K} \}} ,$$

[symbol]

∈R^{{M×N×C}} and for a DNN classifier [symbol] ∈R^{{N}^{_{c}}}, N_{c} is the number of classes and subscript K represents the compression factor. [symbol] depends on the objective of the DNN whether it is classifier, regressor or generator. Without loss of generality, we will assume the classifier case here.

The setup provides us with two types of supervision, one type is through ground truth labels Yₜᵣᵤₑ∈B^{{N}^{_{c}}} and the other one is the reconstruction loss (e.g., in form of mean-square error) between the input to the DySw subnetwork and the output of the DySw subnetwork. Additionally, if DyFsNet is initialized with a pretrained DNN, it is possible to use knowledge distillation loss between the outputs of the pretrained DNN, Y_{KD} and the output of DySw subnetwork. For convenience we can refer to loss calculated with Y_{True} and Y_{KD} supervision as global-loss and the reconstruction−loss(yₗ, [symbol] ) across DySw as the local loss. The different types of losses to be optimized during training the network are shown below,

DyFsNet trained from scratch:

$$Loss = λ * {loss}_{\{ cross - entropy \}} ( {Y}_{true} , ) + ( 1 - λ ) {loss}_{reconstruction} ( {y}_{l} , ) ,$$

$$s . t .$$

$$0 \leq λ \leq 1$$

$${θ}^{*} = {arg min}_{θ} ( Loss )$$

DyFsNet trained using pretrained initializations:

$$Loss = {λ}_{1} * {loss}_{\{ cross - entropy \}} ( {Y}_{true} , ) + {λ}_{2} {loss}_{reconstruction} ( {y}_{l} , ) + {λ}_{3} {loss}_{KD} ( {Y}_{KD} , ) ,$$

$$s . t .$$

$${λ}_{1} + {λ}_{2} + {λ}_{3} = 1$$

$$and$$

$$1 \geq {λ}_{1} , {λ}_{2} , {λ}_{3} \geq 0$$

$${θ}_{DySw}^{*} = {arg min}_{{θ}_{DySw}} ( Loss )$$

Multi-split DyFsNet trained from scratch:

$$\begin{matrix}Loss = λ * {loss}_{\{ cros s - e n t r o p y \}} ( {Y}_{true} , ) + ( 1 - λ ) {\sum }_{l = 1}^{L} {loss}_{reco n s t r u c t i o n} ( {y}_{t} , ) , \\ s . t . 0 \leq λ \leq 1 \\ {θ}_{DyFs N e t}^{*} = {argmin}_{{θ}_{DyFsNet}} ( Loss )\end{matrix}$$

Multi-split DyFsNet trained from pretrained initialization:

$$Loss = {λ}_{1} * l o s {s}_{\{ cross - entropy \}} ( {Y}_{true} , ) \text{} + {λ}_{2} {\sum }_{l = 1}^{L} {loss}_{reconstruction} ( {y}_{l} , ) \text{} + {λ}_{3} {loss}_{KD} ( {Y}_{KD} , ) ,$$

$$s . t . {λ}_{1} + {λ}_{2} + {λ}_{3} = 1 and 1 \geq {λ}_{1} , {λ}_{2} , {λ}_{3} \geq 0$$

$${θ}_{DySw}^{*} = {argmin}_{{θ}_{DySw}} ( Loss )$$

### DyFsNet Training Algorithm

Let (Xᵢ, Yᵢ)∈D be dataset where Xᵢ and Yᵢ are data and its supervision respectively, i∈{0, 1, . . . , N} is the index, N is the number of training samples and Num-of-epochs is the number of training epochs. Here we give the training algorithm for a classifier using global losses, i.e., cross-entropy and KD. KD based loss can be four types—with a distillation from: i) output of a DySw without compression (i.e., DySw with K=1), ii) output of a DySw with immediate lower compression factor (i.e., distillation from DySw with K=K1 to K=K2 where K1<K2), iii) affine combination of uncompressed DySw output and the closest compressed DySw ouput/s, or iv) output of a completely different DNN architecture well-trained for the same task.

The overall algorithm is as follows:
a. Calculate loss of the DyFsNet for the uncompressed configuration of DySw. In our example it is cross-entropy loss but not restricted to just that.
b. Do backpropagation and accumulate the gradients for the uncompressed configuration of DySw.
c. Choose Nᵣ number of CFs in the range 1 to C where 1 represents uncompressed and C represents maximum compression.
d. For CF=2 to Nᵣ:
   i. Calculate loss of DyFsNet for distillation type (i), (ii), (iii), or (iv)
   ii. Do backpropagation and accumulate gradients for DySw
e. Update weights using the accumulated gradients.

In one example, the following pseudo-codes are used.

KD from uncompressed (K=1) DySw output:

```
For n in range (Num-of-epochs) DO:
    For i in range (N) DO:
          // Forward pass through DyFsNet without compression i.e.,
  compression factor K=C [symbol]
      h_{device2}(h_{DySw}(h_device1(Xᵢ)))
            Calculate loss: loss_{{cross-entropy}}(Yₜᵣᵤₑ, [symbol]   )
        Do loss-Backpropagation and accumulate gradients
      // Sample Nᵣ random numbers where Nᵣ <= C
      // Let S be a set of Nᵣ random numbers
      // Note each element in S represents a compression factor
    (CF) ascending order
      S = random (1, C, size= Nᵣ)
      For j in range (Nᵣ) :
              K = S [j]
              Y_{K} = h_{device2}(h_{DySw}(h_device1(Xᵢ)))
                Calculate KD loss: loss_{{KD}}( [symbol]   , [symbol]   )
                Do loss-Backpropagation and accumulate gradients
          END For
        Update weights of DyFsNet (whole or just the DySw if using
    fixed pretrained weights)
    End For
End For
```

KD from the output of DySw having K=K1 to DySw having K=K2 where K1<K2:

```
For n in range (Num-of-epochs) DO:
  For i in range (N) DO:
    // Sample Nr random numbers where Nᵣ <= C
    // Let S be a set of Nᵣ random numbers
    // Note each element in S represents a compression factor
  (CF) in ascending order
    S = random (1, C, size= Nᵣ)
        // Forward pass through DyFsNet without compression i.e.,
compression factor K=C [symbol]
    =h_{device2}(h_{DySw}(h_device1(Xᵢ)))
          Calculate loss: loss_{{cross-entropy}}(Yₜᵣᵤₑ, [symbol]   )
      Do loss-Backpropagation and accumulate gradients
    For j in range (2, Nᵣ) :
            K = S [j]
            Y_{K} = h_{device2}(h_{DySw}(h_device1(Xᵢ)))
              Calculate KD loss: loss_{{KD}}( [symbol]   , [symbol]   )
              Do loss-Backpropagation and accumulate gradients
        END For
      Update weights of DyFsNet (Whole or just the DySw if using
  fixed pretrained weights)
  End For
End For
```

KD from the output of DySw having K=K1 to DySw having K=K2 where K1<K2:

```
For n in range (Num-of-epochs) DO:
  For i in range (N) DO:
    // Sample Nᵣ random numbers where Nᵣ <= C
    // Let S be a set of Nᵣ random numbers
    // Note each element in S represents a compression factor
  (CF) in ascending order
    s = random (1, C, size= Nᵣ)
        // Forward pass through DyFsNet without compression i.e.,
compression factor K=C [symbol]
    = h_{device2}(h_{DySw}(h_device1(Xᵢ)))
          Calculate loss: loss_{{cross-entropy}}(Yₜᵣᵤₑ, [symbol]   )
      Do loss-Backpropagation and accumulate gradients
    For j in range (2, Nᵣ) :
            K = S [j]
            Y_{K} = h_{device2}(h_{DySw}(h_device1(Xᵢ)))
              Calculate KD loss: Σₜ₌₁^{j-1} λₜ loss_{{KD}}( [symbol]   , [symbol]   )
              do loss-Backpropagation and accumulate gradients
        END For
      Update weights of DyFsNet (whole or just the DySw if using
  fixed pretrained weights)
  END For
End For
```

We tested the proposed idea for image classification task using the well-known MSDNet model. This model has several CNN blocks where classification can be done at the outputs of any blocks. We want to split this large network at the end of different blocks and transmitting the corresponding feature to a second device (or cloud). The feature dimension for the MSDNet at the end of each block for ImageNet dataset is show in Table 1.

TABLE 1

| | Approximate output | |
|---|---|---|
| | data size (MByte) per | Required |
| | Input Image | UL data rate |
| Split point | (224 × 224 × 3) | (Mbps) |
| Candidate split point 0 | 0.14 | 34 |
| (Cloud-based inference) | | |
| Candidate split point 1 | 2.15 | 516.72 |
| (after block 1) | | |
| Candidate split point 2 | 1.00 | 241.17 |
| (after block 2) | | |
| Candidate split point 3 | 0.33 | 78.95 |
| (after block 3) | | |
| Candidate split point 4 | 0.056 | 13.63 |
| (after block 4) | | |

We illustrate here the utility of feature size reduction through an illustration of a data-rate requirement in a typical DNN. Data-rate required for transmitting a feature corresponding to a single image of size 224×224×3 generated in a DNN used for image classification (MSDNet) is in the range of 13 Mbps to 0.5 Gbps. This is a challenging data-rate for a transmission on wireless networks. In a preliminary implementation of our approach using MSDNet model we were able to reduce feature size by 50% with at most 1% of loss in accuracy.

In the following, we describe our implementation of DySw in MSDNet for CIFAR-100 the DNN is split at seven locations and the feature size (each unit is 16 bits) at each split location is shown in Table 2. We have realized compression factors of 1, 2, 4 and 10.

TABLE 2

| | Feature Size |
|---|---|
| Split locations | (size in 16 bits) |
| 1 | 10240 |
| 2 | 13312 |
| 3 | 8960 |
| 4 | 12032 |
| 5 | 15104 |
| 6 | 9728 |
| 7 | 12800 |

To investigate the effect of adding the bandwidth reducer-expander in the MSDNet. We show the results for the cases of baseline (without bandwidth reducer-expander) and with bandwidth reducer-expander for the cases of reduction factor 1, 2, 4 and 10 in Table 3. The reduction factors 1, 2, 4 and 10 corresponds to 100%, 50%, 25% and 10% of the original bandwidth, respectively. One can see that the accuracy of the bandwidth reduced MSDNet is almost the same as the baseline MSDNet without any reduction. Note the accuracy is for the compression implementation at end of all six blocks (0 to 6) and all the scales. In other words, by adding a new bandwidth-reducer-expander at each split point, the feature can be greatly reduced to support the feature transmission, while classification accuracy is almost unchanged.

TABLE 3

| | Block-0 | Block-1 | Block-2 | Block-3 | Block-4 | Block-5 | Block-6 |
|---|---|---|---|---|---|---|---|
| Compression | (Top-1 | (Top-1 | (Top-1 | (Top-1 | (Top-1 | (Top-1 | (Top-1 |
| factor | Acc. %) | Acc. %) | Acc. %) | Acc. %) | Acc. %) | Acc. %) | Acc. %) |
| Baseline | 65.05 | 67.7 | 70.88 | 71.78 | 72.35 | 73.67 | 73.79 |
| K = 1 | 65.04 | 67 | 69 | 71 | 72 | 72 | 72.2 |
| K = 2 | 65.64 | 69.54 | 69.91 | 71.05 | 71.6 | 71.34 | 71.78 |
| K = 4 | 64.37 | 68.42 | 69.99 | 71.76 | 72.22 | 72.65 | 72.61 |
| K = 10 | 65.05 | 67.28 | 68.15 | 68.49 | 69.48 | 69.75 | 70.38 |

There have been methods of switchable precision networks which refer to the precision of the CNN weights. There has also been a work on the switchable multiple width CNNs. But unlike them we propose a switchable feature bandwidth networks which can at the inference time switch between different feature bandwidths. This switchability is useful to deal with the bandwidth constraints of the communication channel between devices or device-cloud or other combination thereof. This mechanism can be used agnostic to the CNN architectures, for example it can be used seamlessly with existing models performing different machine learning tasks like ResNet, AlexNet, DenseNet, SoundNet, VGG, and others. This mechanism can also be used agnostic to other types of feature compression techniques such as weight quantization.

The proposed approach deals with efficient bandwidth for transmission for distributed AI with a provision to switch among multiple feature bandwidths. During the distributed inference at edge devices, each device needs to load part of the AI model only one time, but the input/output features communicated between them can be flexibly configured depending on the available transmission bandwidth by enabling/disabling connection between nodes in the DySw. When some nodes are connected or disconnected in order to achieve the desired compression factor, other parameters of the DNN remain the same. That is, the same DNN model is used for different compression factors, and no new DNN model needs to be downloaded to adapt to the compression factor or the network bandwidth.

The AI processing can be used, for example, but not limited to, on images shot on a basic phone's camera, or on images shot from a smart TV camera for UI interaction via gesture detection. The proposed approach can be used in various scenarios. For instance, the AI model can be split between device and cloud. In the following, we list several possible usage scenarios:
1. AI model split between two devices. For example, the user wants to process data captured in the smart watch, where a part of processing can be done on the watch and the rest on the user's mobile phone.
2. AI model split between multiple devices and possibly cloud. For example, the user wants to process the feed of the smart CCTV camera quickly on the camera itself and a detailed processing on the cloud or a local server.
3. Like use-case 3 but with speech/audio processing with a compute enabled microphone instead of a CCTV camera.
4. Sharing the processing of medical data diagnostic room and cloud.
5. A terminal device that may communicate over a wireless link, where the AI processing is related to a function of a transmission and/or a reception of radio processing chain (e.g., CSI compression, CSI autoencoding, positioning determination, or the likes).
6. A terminal device that may communicate over a wireless link, where the AI processing is related to a function of a scheduling or data processing e.g., related to QoS processing (e.g., user plane data rate adaptation or the likes).

Various numeric values are used in the present application. The specific values are provided for example purposes and the aspects described are not limited to these specific values.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer readable medium for execution by a computer or processor. Examples of non-transitory computer-readable storage media include, but are not limited to, a read only memory (ROM), random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a video encoder, a video decoder or both, a radio frequency transceiver for use in a UE, WTRU, terminal, base station, RNC, or any host computer.

Moreover, in the embodiments described above, processing platforms, computing systems, controllers, and other devices containing processors are noted. These devices may contain at least one Central Processing Unit (“CPU”) and memory. In accordance with the practices of persons skilled in the art of computer programming, reference to acts and symbolic representations of operations or instructions may be performed by the various CPUs and memories. Such acts and operations or instructions may be referred to as being “executed,” “computer executed” or “CPU executed”.

One of ordinary skill in the art will appreciate that the acts and symbolically represented operations or instructions include the manipulation of electrical signals by the CPU. An electrical system represents data bits that can cause a resulting transformation or reduction of the electrical signals and the maintenance of data bits at memory locations in a memory system to thereby reconfigure or otherwise alter the CPU's operation, as well as other processing of signals. The memory locations where data bits are maintained are physical locations that have particular electrical, magnetic, or optical properties corresponding to or representative of the data bits. It should be understood that the exemplary embodiments are not limited to the above-mentioned platforms or CPUs and that other platforms and CPUs may support the provided methods.

The data bits may also be maintained on a computer readable medium including magnetic disks, optical disks, and any other volatile (e.g., Random Access Memory (“RAM”)) or non-volatile (e.g., Read-Only Memory (“ROM”)) mass storage system readable by the CPU. The computer readable medium may include cooperating or interconnected computer readable medium, which exist exclusively on the processing system or are distributed among multiple interconnected processing systems that may be local or remote to the processing system. It is understood that the representative embodiments are not limited to the above-mentioned memories and that other platforms and memories may support the described methods.

In an illustrative embodiment, any of the operations, processes, etc. described herein may be implemented as computer-readable instructions stored on a computer-readable medium. The computer-readable instructions may be executed by a processor of a mobile unit, a network element, and/or any other computing device.

The use of hardware or software is generally (but not always, in that in certain contexts the choice between hardware and software may become significant) a design choice representing cost vs. efficiency tradeoffs. There may be various vehicles by which processes and/or systems and/or other technologies described herein may be effected (e.g., hardware, software, and/or firmware), and the preferred vehicle may vary with the context in which the processes and/or systems and/or other technologies are deployed. For example, if an implementer determines that speed and accuracy are paramount, the implementer may opt for a mainly hardware and/or firmware vehicle. If flexibility is paramount, the implementer may opt for a mainly software implementation. Alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples may be implemented, individually and/or collectively, by a wide range of hardware, software, firmware, or virtually any combination thereof. Suitable processors include, by way of example, a GPU (Graphics Processing Unit), a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Application Specific Standard Products (ASSPs), Field Programmable Gate Arrays (FPGAs) circuits, any other type of integrated circuit (IC), and/or a state machine.

Although features and elements are provided above in particular combinations, one of ordinary skill in the art will appreciate that each feature or element can be used alone or in any combination with the other features and elements. The present disclosure is not to be limited in terms of the particular embodiments described in this application, which are intended as illustrations of various aspects. Many modifications and variations may be made without departing from its spirit and scope, as will be apparent to those skilled in the art. No element, act, or instruction used in the description of the present application should be construed as critical or essential to the invention unless explicitly provided as such. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods or systems.

It is also to be understood that the terminology used herein is for the purpose of describing particular embodiments only, and is not intended to be limiting.

In certain representative embodiments, several portions of the subject matter described herein may be implemented via Application Specific Integrated Circuits (ASICs), Field Programmable Gate Arrays (FPGAs), digital signal processors (DSPs), and/or other integrated formats. However, those skilled in the art will recognize that some aspects of the embodiments disclosed herein, in whole or in part, may be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein may be distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a CD, a DVD, a digital tape, a computer memory, etc., and a transmission type medium such as a digital and/or an analog communication medium (e.g., a fiber optic cable, a waveguide, a wired communications link, a wireless communication link, etc.).

The herein described subject matter sometimes illustrates different components contained within, or connected with, different other components. It is to be understood that such depicted architectures are merely examples, and that in fact many other architectures may be implemented which achieve the same functionality. In a conceptual sense, any arrangement of components to achieve the same functionality is effectively “associated” such that the desired functionality may be achieved. Hence, any two components herein combined to achieve a particular functionality may be seen as “associated with” each other such that the desired functionality is achieved, irrespective of architectures or intermediate components. Likewise, any two components so associated may also be viewed as being “operably connected”, or “operably coupled”, to each other to achieve the desired functionality, and any two components capable of being so associated may also be viewed as being “operably couplable” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, where only one item is intended, the term “single” or similar language may be used. As an aid to understanding, the following appended claims and/or the descriptions herein may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”). The same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, the terms “any of” followed by a listing of a plurality of items and/or a plurality of categories of items, as used herein, are intended to include “any of,” “any combination of,” “any multiple of,” and/or “any combination of multiples of” the items and/or the categories of items, individually or in conjunction with other items and/or other categories of items. Moreover, as used herein, the term “set” or “group” is intended to include any number of items, including zero. Additionally, as used herein, the term “number” is intended to include any number, including zero.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein may be readily broken down into a lower third, middle third and upper third, etc. As will also be understood by one skilled in the art all language such as “up to,” “at least,” “greater than,” “less than,” and the like includes the number recited and refers to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Moreover, the claims should not be read as limited to the provided order or elements unless stated to that effect. In addition, use of the terms “means for” in any claim is intended to invoke 35 U.S.C. § 112, ¶6 or means-plus-function claim format, and any claim without the terms “means for” is not so intended.

It is contemplated that the systems may be implemented in software on microprocessors/general purpose computers (not shown). In certain embodiments, one or more of the functions of the various components may be implemented in software that controls a general-purpose computer.

In addition, although the invention is illustrated and described herein with reference to specific embodiments, the invention is not intended to be limited to the details shown. Rather, various modifications may be made in the details within the scope and range of equivalents of the claims and without departing from the invention.

1. A Wireless Transmit/Receive Unit (WTRU), comprising:
a receiver configured to receive a part of a Deep Neural Network (DNN) model, wherein said part is before a split point of said DNN model, and wherein said part of said DNN model includes a neural network to compress feature at said split point of said DNN model;
one or more processors configured to:
obtain a compression factor for said neural network,
determine which nodes in said neural network are to be connected responsive to said compression factor,
configure said neural network responsive to said determining, and
perform inference with said part of said DNN model to generate compressed feature; and
a transmitter configured to transmit said compressed feature to another WTRU.

2. The device of claim 1, wherein said transmitter is further configured to send an indication of said obtained compression factor to said another WTRU.

3-5. (canceled)

6. The device of claim 1, wherein said one or more processors are configured to determine which nodes in said network are to be connected when said compression factor is adjusted.

7-11. (canceled)

12. The device of claim 1, wherein at least one of said split point and said compression factor is adapted based on one or more of (1) physical layer operations, (2) Media Access Control layer operations, (3) Radio Resource Control layer operations, (4) available processing resources and (5) control signaling.

13. The device of claim 1, wherein at least one of said split point and said compression factor is adapted based on a transmission data rate.

14. (canceled)

15. A method performed by a Wireless Transmit/Receive Unit (WTRU), the method comprising:
receiving a part of a Deep Neural Network (DNN) model, wherein said part is before a split point of said DNN model, and wherein said part of said DNN model includes a neural network to compress feature at said split point of said DNN model;
obtaining a compression factor for said neural network;
determining which nodes in said neural network are to be connected responsive to said compression factor;
configuring said neural network responsive to said determining;
performing inference with said part of said DNN model to generate compressed feature; and
transmitting said compressed feature to another WTRU.

16. The method of claim 15, further comprising sending an indication of said obtained compression factor to said another WTRU.

17-19. (canceled)

20. The method of claim 15, wherein which nodes in said network are to be connected are determined when said compression factor is adjusted.

21-24. (canceled)

25. The method of claim 15, wherein only one DNN model is loaded to said device for different compression factors.

26. The method of claim 15, wherein at least one of said split point and said compression factor is adapted based on one or more of (1) physical layer operations, (2) Media Access Control layer operations, (3) Radio Resource Control layer operations, (4) available processing resources and (5) control signaling.

27-29. (canceled)

30. A Wireless Transmit/Receive Unit (WTRU), comprising:
a receiver configured to receive a part of a Deep Neural Network (DNN) model, wherein said part is after a split point of said DNN model, and wherein said part of said DNN model includes a neural network to expand feature at said split point of said DNN model, wherein said receiver is also configured to receive one or more features output from another WTRU; and
one or more processors configured to:
obtain a compression factor for said neural network,
determine which nodes in said neural network are to be connected responsive to said compression factor,
configure said neural network responsive to said determining, and
perform inference with said part of said DNN model, using said one or more features output from another WTRU as input to said neural network.

31. The device of claim 30, wherein said receiver is further configured to receive a signal indicative of said compression factor.

32. The device of claim 30, wherein said one or more processors are configured to determine which nodes in said network are to be connected when said compression factor is adjusted.

33. The device of claim 30, wherein only one DNN model is loaded to said device for different compression factors.

34. The device of claim 30, wherein at least one of said split point and said compression factor is adapted based on one or more of (1) physical layer operations, (2) Media Access Control layer operations, (3) Radio Resource Control layer operations, (4) available processing resources and (5) control signaling.

35. A method, comprising:
receiving a part of a Deep Neural Network (DNN) model, wherein said part is after a split point of said DNN model, and wherein said part of said DNN model includes a neural network to expand feature at said split point of said DNN model;
receiving one or more features output from another WTRU;
obtaining a compression factor for said neural network;
determining which nodes in said neural network are to be connected responsive to said compression factor;
configuring said neural network responsive to said determining; and
performing inference with said part of said DNN model, using said one or more features output from another WTRU as input to said neural network.

36. The method of claim 35, further comprising receiving a signal indicative of said compression factor.

37. The method of claim 35, wherein which nodes in said network are to be connected are determined when said compression factor is adjusted.

38. The method of claim 35, wherein only one DNN model is loaded to said device for different compression factors.

39. The method of claim 35, wherein at least one of said split point and said compression factor is adapted based on one or more of (1) physical layer operations, (2) Media Access Control layer operations, (3) Radio Resource Control layer operations, (4) available processing resources and (5) control signaling.
